(19) United States
(12) Patent Application Publication
(10) Pub. No.: US 2010/0142302 A1
(43) Pub. Date: Jun. 10, 2010

(54) SEMICONDUCTOR MEMORY DEVICE AND TESTING METHOD THEREFOR

(75) Inventor: Yuki HOSOE, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/633,503

(22) Filed: Dec. 8, 2009

(30) Foreign Application Priority Data
Dec. 9, 2008 (JP) 2008-313751

(51) Int. Cl. G11C 29/00; G11C 8/00

(52) U.S. Cl. 365/201; 365/230.03

(57) ABSTRACT

A semiconductor memory device includes memory blocks, a redundancy determining circuit that can enter in a parallel test mode in which the both memory blocks are simultaneously accessed, and a verifying circuit that verifies data read from the memory blocks. When accessing normal cell areas of the memory blocks simultaneously, in response to a fact that at least one of the memory blocks is replaced by a redundancy memory cell, the redundancy determining circuit supplies pass signals indicating a memory block in which replacement is performed to the verifying circuit. Based on the pass signals, the verifying circuit passes verification of data read from the memory block in which the replacement is performed.

### BACKGROUND OF THE INVENTION

1. Field of the Invention

The present invention relates to a semiconductor memory device and a testing method therefor, and more particularly relates to a semiconductor memory device including a parallel test mode for accessing a plurality of memory blocks simultaneously, and a testing method for the semiconductor memory device.

2. Description of Related Art

A memory density of a semiconductor memory device represented by DRAM (Dynamic Random Access Memory) is increasing year by year with the development of downscaling techniques. However, the development of downscaling techniques also causes an increase of the number of defective memory cells per chip. Such defective memory cells are replaced by redundancy memory cells, to thus defective addresses are relieved.

Even after defective memory cells are replaced by redundancy memory cells, various tests are performed for the semiconductor memory device. However, because the recent semiconductor memory device has a considerably large memory address space, a considerably long test time is required when such tests are performed with conventional I/O circuits. As a method to deal with this problem, a parallel test has been widely employed (see Japanese Patent Application Laid-open No. 2008-108390). The parallel test is a method to simultaneously testa plurality of memory cells on a selected word line by internally verifying a plurality of data read from a memory cell array in the semiconductor memory device. With this test method, it is possible to greatly reduce the test time, compared with a case of performing the test with conventional I/O circuits.

Such a parallel test is performed for both a normal cell area constituted by a plurality of normal memory cells and a redundancy cell area constituted by a plurality of redundancy memory cells. However, a normal memory cell that is already replaced by a redundancy memory cell and a redundancy memory cell that is not used as a replacement destination for a normal memory cell that is defective are not accessed at the point of practical use. Therefore, it is not necessary to perform the test for those memory cells. In Japanese Patent Application Laid-open No. 2008-108390, the parallel test is passed for those memory cells not accessed at the practical use (determined as normal).

To further reduce the test time, the number of memory cells to be simultaneously tested in the parallel test should be increased. As a method of increasing the number of memory cells to be simultaneously tested in the parallel test, accessing simultaneously a plurality of memory blocks in the parallel test and verifying data read from the memory blocks is one approach. In this approach, a plurality of word lines are accessed simultaneously, and data read from a plurality of memory cells connected to the selected word lines are verified simultaneously.

However, if this method is applied to the test method described in Japanese Patent Application Laid-open No. 2008-108390 as it is, it can cause the following problems. For example, considering a case where two memory blocks are accessed simultaneously in the parallel test, if a normal memory cell that is not replaced by a redundancy memory cell (that is, a normal memory cell that is not defective) is accessed in one of the memory blocks and a normal memory cell that is replaced by a redundancy memory cell (that is, a normal memory cell that is defective) is accessed in the other memory block, a result of the test with the method of Japanese Patent Application Laid-open No. 2008-108390 will indicate a pass (determined as normal) in a forcible manner. This means that, in this case, the test is not performed for the normal memory cell that is not replaced by a redundancy memory cell.

The same problem occurs in a test for a redundancy cell area. That is, if a redundancy memory cell that is used as a replacement destination for a normal memory cell that is defective is accessed in the one memory block and a redundancy memory cell that is not used as a replacement destination for a normal memory block that is defective is accessed in the other memory block, a result of the test will indicate a pass (determined as normal) in a forcible manner. This means that, in this case, the test is not performed for the redundancy memory cell that is used as the replacement destination for the normal memory cell that is defective.

As described above, when accessing a plurality of memory blocks simultaneously in a parallel test, there has been a problem that a test is not properly performed for a memory cell to be tested, depending on a replacement status of a normal memory cell.

### SUMMARY

The present invention seeks to solve one or more of the above problems, or to improve upon those problems at least in part.

In one embodiment, there is provided a semiconductor memory device comprising: a first memory block and a second memory block each including a normal cell area having a plurality of normal memory cells and a redundancy cell area having a plurality of redundancy memory cells for replacing a defective memory cell among the normal memory cells; a redundancy determining circuit that can enter at least a normal operation mode in which either one of the first and second memory blocks is accessed and a parallel test mode in which both the first and second memory blocks are simultaneously accessed; and a verifying circuit that verifies data read from the first and second memory blocks in the parallel test mode, wherein the redundancy determining circuit supplies the verifying circuit with a pass signal in response to a fact that a replacement from the normal memory cell to be accessed with the redundancy memory cell is performed in at least one of the first and second memory blocks when accessing the normal cell areas of the first and second memory blocks simultaneously in the parallel test mode, and the verifying circuit passes verification of data read from the normal cell area of the memory block in which the replacement is performed and exclusively performs verification of data read from the normal cell area of the memory block in which replacement is not performed based on the pass signal.

In another embodiment, there is provided a testing method of a semiconductor memory device that includes a first memory block and a second memory block each having a normal cell area having a plurality of normal memory cells and a redundancy cell area having a plurality of redundancy memory cells for replacing a defective memory cell among the normal memory cells, the method comprising: accessing the normal cell areas of the first and second memory blocks simultaneously; and verifying data read from the first and second memory blocks, wherein if the normal memory cell to be accessed is replaced with the redundant memory cell in at least one of the first and second memory blocks, verifying is passed with respect to a memory block in which a replacement is performed, and exclusively verifying the read data with respect to a memory block in which a replacement is not performed.

According to the present invention, in a parallel test, when a normal memory cell that is not replaced by a redundancy memory cell is accessed in one memory block and a normal memory cell that is replaced by a redundancy memory cell is accessed in another memory block, only data read from the another memory block is passed without passing data read from the one memory block. As a result, it is possible to solve the problem of not performing the test for the normal memory cell that is not replaced by the redundancy memory cell.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram of a semiconductor memory device 10 according to a preferred embodiment of the present invention;

FIG. 2 is a partial circuit diagram of the memory cell array 11;

FIG. 3 is a block diagram showing the memory cell array 11 in detail;

FIG. 4 is a block diagram of a circuit configuration of the X redundancy determining circuit 100X;

FIG. 5 is a timing chart showing an operation of the X redundancy determining circuit 100X in the first parallel test mode;

FIG. 6 is a block diagram of a circuit configuration of the Y redundancy determining circuit 100Y; and

FIG. 7 is a timing chart showing an operation of the Y redundancy determining circuit 100Y in the first parallel test mode.

### DETAILED DESCRIPTION OF THE EMBODIMENTS

Preferred embodiments of the present invention will be explained below in detail with reference to the accompanying drawings.

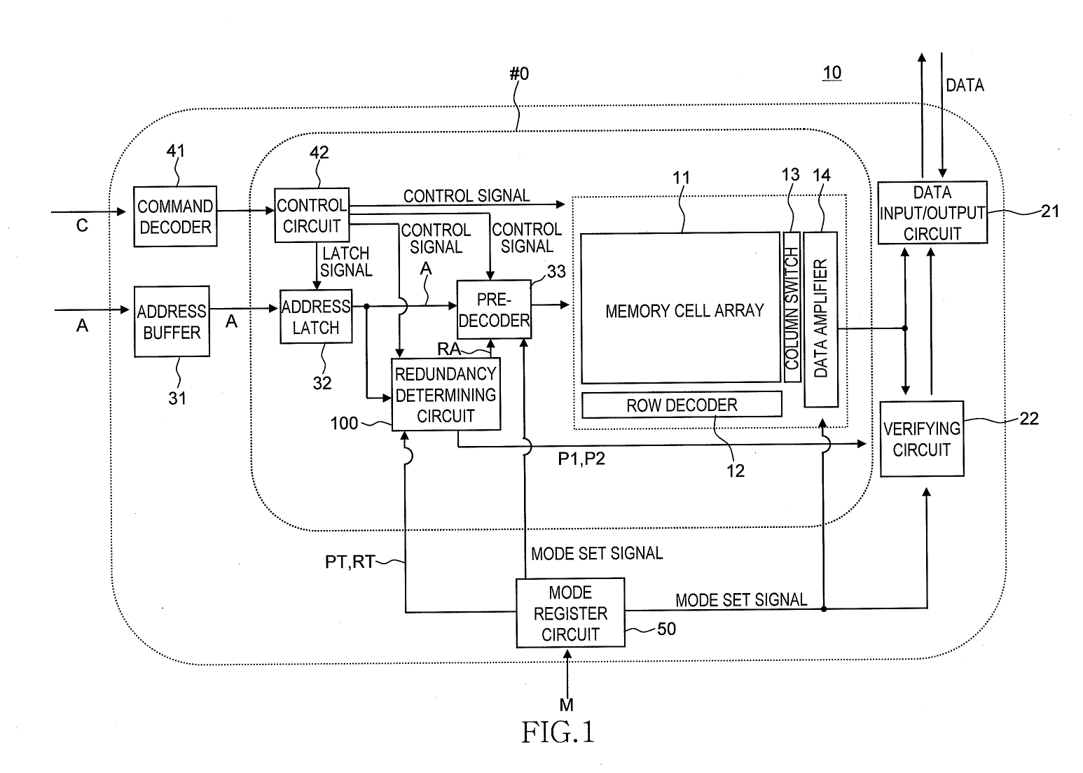

FIG. 1 is a block diagram of a semiconductor memory device 10 according to an embodiment of the present invention.

As shown in FIG. 1, a bank #0 provided in the semiconductor memory device 10 includes a memory cell array 11 that includes a plurality of memory cells, a row decoder 12 that selects a word line included in the memory cell array 11, a column switch 13 that selects a bit line included in the memory cell array 11, and a data amplifier 14 that amplifies data to be input or output to or from a memory cell that is selected by the row decoder 12 and the column switch 13. Although the semiconductor memory device 10 includes a plurality of banks having the same configuration as the bank #0, these banks are not shown in FIG. 1.

Read data output from the data amplifier 14 is output to the outside of the semiconductor memory device 10 via a data input/output circuit 21. The read data is also supplied to a verifying circuit 22 at the time of a parallel test, which is described later. The verifying circuit 22 is a circuit that verifies a status (normal or defective) of the memory cell by comparing a plurality of data output from the data amplifier 14 with each other. Methods of comparing the data include a method of comparing the data output from the data amplifier 14 with each other and a method of comparing the data output from the data amplifier 14 with expectation value data written in a register (not shown); however, either one of the methods can be used. A result of verification by the verifying circuit 22 is output to the outside via the data input/output circuit 21.

On the other hand, write data input from the outside via the data input/output circuit 21 is supplied to the memory cell array 11 via the data amplifier 14. As described later, the memory cell array 11 is divided by a first memory block and a second memory block. Each of the memory blocks includes a normal cell area constituted by a plurality of normal memory cells and a redundancy cell area constituted by a plurality of redundancy memory cells for replacing a normal memory cell that is defective.

An address A supplied from the outside is supplied to the row decoder 12 and the column switch 13 via an address buffer 31, an address latch circuit 32, and a pre-decoder 33. The address A latched in the address latch circuit 32 is also supplied to a redundancy determining circuit 100. When the input address A indicates a normal memory cell that is defective, the redundancy determining circuit 100 converts the address A into a redundancy address RA, and supplies the redundancy address RA to the pre-decoder 33.

When the pre-decoder 33 receives the redundancy address RA from the redundancy determining circuit 100 (the case of hit), the pre-decoder 33 supplies a pre-decoded signal obtained by pre-decoding the redundancy address RA to the row decoder 12 and the column switch 13. When the pre-decoder 33 does not receive the redundancy address RA from the redundancy determining circuit 100 (the case of miss-hit), the pre-decoder 33 supplies a pre-decoded signal obtained by pre-decoding a regular address A to the row decoder 12 and the column switch 13. With this arrangement, a normal memory cell that is defective is replaced by a redundancy memory cell, so that an address indicating the normal memory cell that is defective (a defective address) can be saved. An output timing at which the pre-decoder 33 outputs the pre-decoded signal is determined based on a control signal from a control circuit 42.

Various commands C supplied from the outside are interpreted by a command decoder 41, and a result of interpretation is supplied to the control circuit 42. The commands C include a row address strobe (RAS) signal, a column address strobe (CAS) signal, and a write enable (WE) signal. Upon receiving a result of decoding the commands C, the control circuit 42 supplies a latch signal to the address latch circuit 32, and at the same time, supplies various control signals to the pre-decoder 33 and the redundancy determining circuit 100. With this arrangement, an overall operation of the semiconductor memory device 10 is controlled.

The semiconductor memory device 10 according to the present embodiment further includes a mode register circuit 50. The mode register circuit 50 is a register of which content is set by a reception of a mode select signal M, and outputs a mode set signal in response to the set content. The mode set signal is supplied to the pre-decoder 33, the redundancy determining circuit 100, the verifying circuit 22, and the like. The mode select signal M can be either one of a signal that is directly supplied from the outside and a signal supplied via the address buffer 31.

An operation mode set in the mode register circuit 50 includes at least a normal operation mode that is set when performing a normal operation of the semiconductor memory device and a parallel test mode that is set when performing a parallel test of the semiconductor memory device. When the operation mode of the mode register circuit 50 is set to the parallel test mode, the mode register circuit 50 activates a parallel test signal PT. Furthermore, the parallel test mode includes at least a first parallel test mode in which a test is performed for the normal cell area and a second parallel test mode in which a test is performed for the redundancy cell area. When the operation mode of the mode register circuit 50 is set to the second parallel test mode, the mode register circuit 50 activates a redundancy test signal RT. The parallel test signal PT and the redundancy test signal RT are supplied at least to the redundancy determining circuit 100.

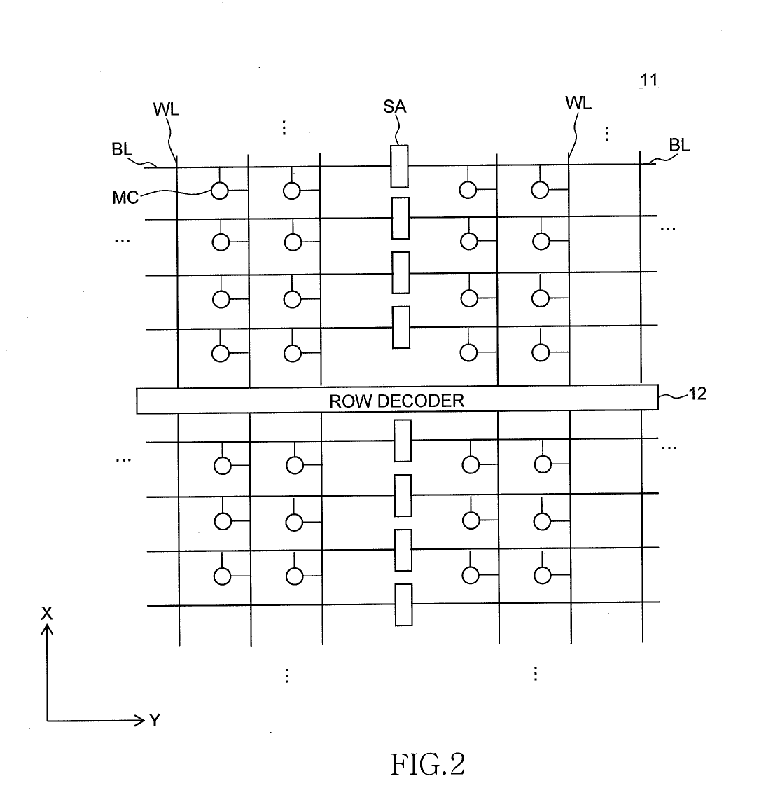

FIG. 2 is a partial circuit diagram of the memory cell array 11.

As shown in FIG. 2, the memory cell array 11 includes a plurality of word lines WL extending in an X direction, a plurality of bit lines BL extending in a Y direction, and a plurality of memory cells MC each arranged at an intersection of each of the word lines WL with each of the bit lines BL. In the present embodiment, the memory cells MC are DRAM cells, which are constituted by a serial circuit of a cell transistor and a cell capacitor. A gate electrode of the cell transistor is connected to a corresponding one of the word lines WL, and a source electrode or a drain electrode is connected to a corresponding one of the bit lines BL.

The word lines WL are connected to the row decoder 12 that extends in the Y direction, and activated by a row address. The bit lines BL are respectively connected to sense amplifiers SA arranged in the X direction. The sense amplifiers SA are selected by the column switch 13 shown in FIG. 1.

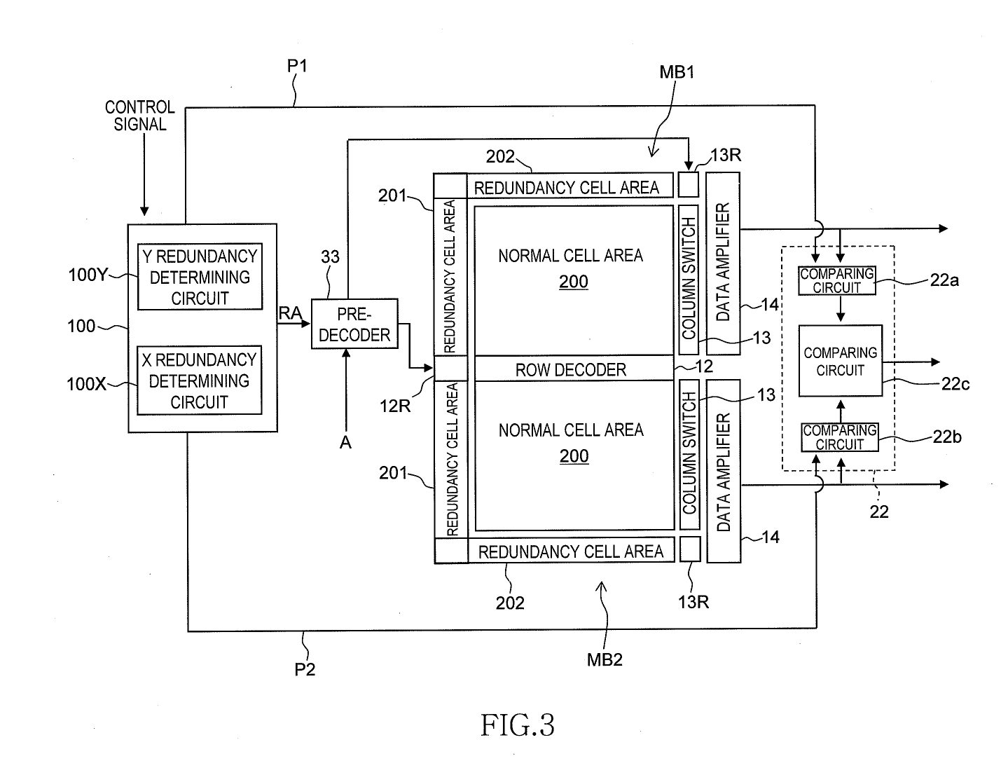

FIG. 3 is a block diagram showing the memory cell array 11 in detail.

As shown in FIG. 3, the memory cell array 11 is divided by a first memory block MB1 and a second memory block MB2. The first memory block MB1 and the second memory block MB2 are differentiated from each other by an uppermost bit X13 of the row address. The column switch 13 and the data amplifier 14 are provided for each of the first memory block MB1 and the second memory block MB2.

Lower bits X12 to X0 of the row address are used for selecting a word line in the memory block. Therefore, in the normal operation mode, a word line included in either one of the first memory block MB1 and the second memory block MB2 is selected based on the row address X13 to X0, and any one of the bit lines is selected based on the column address. As a result, a memory cell included in either one of the first memory block MB1 and the second memory block MB2 is selected, and the selected memory cell is connected to the data amplifier 14.

On the other hand, in the parallel test mode, word lines respectively included in the first memory block MB1 and the second memory block MB2 are selected simultaneously. Accordingly, memory cells respectively included in the first memory block MB1 and the second memory block MB2 are selected simultaneously, and the selected memory cells are connected to the data amplifier 14.

While the row addresses in the present embodiment are constituted by fourteen bits of X13 to X0, the present invention is not limited thereto.

Each of the first memory block MB1 and the second memory block MB2 includes a normal cell area 200 constituted by a plurality of normal memory cells and redundancy cell areas 201 and 202 each constituted by a plurality of redundancy memory cells for replacing a normal memory cell that is defective. Among these areas, the redundancy cell area 201 is an area constituted by redundancy word lines for replacing the word lines included in the normal cell area 200. Meanwhile, the redundancy cell area 202 is an area constituted by a plurality of redundancy bit lines for replacing the bit lines included in the normal cell area 200. The row decoder 12 includes a redundancy row decoder 12R that corresponds to the redundancy cell area 201, and the column switch 13 includes a redundancy column switch 13R that corresponds to the redundancy cell area 202.

The data read from the first memory block MB1 and the second memory block MB2 are supplied to the verifying circuit 22. The verifying circuit 22 includes a comparing circuit 22a that compares a plurality of data read from the first memory block MB1 with each other, a comparing circuit 22b that compares a plurality of data read from the second memory block MB2, and a comparing circuit 22c that compares outputs from the comparing circuits 22a and 22b with each other, and an output of the comparing circuit 22c is the final verification result. The verifying circuit 22 is not limited to the above configuration, but can take another configuration, such as a configuration in which the data read from the first memory block MB1 and the second memory block MB2 are compared with each other as they are. Furthermore, the verifying circuit 22 can be provided by a single circuit in the semiconductor memory device such that it is shared by a plurality of banks as shown in FIG. 1, or can be provided for each of the banks.

As shown in FIG. 3, the redundancy determining circuit 100 includes an X redundancy determining circuit 100X that performs detection of a defective address and generation of a redundancy address for the row address, and a Y redundancy determining circuit 100Y that performs detection of a defective address and generation of a redundancy address for the column address. The redundancy address RA, which is an output of the redundancy determining circuit 100, is supplied to the pre-decoder 33.

The pre-decoder 33 decodes the regular address A and the redundancy address RA. From among outputs of the pre-decoder 33, an output for the row address is supplied to the row decoder 12, and an output for the column address is supplied to the column switch 13. When a row address output from the pre-decoder 33 is an address obtained by decoding the redundancy address RA, it is supplied to the redundancy row decoder 12R included in the row decoder 12, such that a word line of the normal cell area 200 (a normal word line) is not selected, but a word line of the redundancy cell area 201 (a redundancy word line) is selected. Meanwhile, when a column address output from the pre-decoder 33 is an address obtained by decoding the redundancy address RA, it is supplied to the redundancy column switch 13R included in the column switch 13, such that a bit line of the normal cell area 200 (a normal bit line) is not selected, but a bit line of the redundancy cell area 202 (a redundancy bit line) is selected.

Furthermore, the redundancy determining circuit 100 outputs a pass signal P1 designating the first memory block MB1 and a pass signal P2 designating the second memory block MB2. The pass signals P1 and P2 are supplied to the comparing circuits 22a and 22b, respectively. When the pass signals P1 and P2 are activated, the comparing circuits 22a and 22b ignore the data read via the data amplifier 14, and forcibly perform a pass determination (determine that the data are normal).

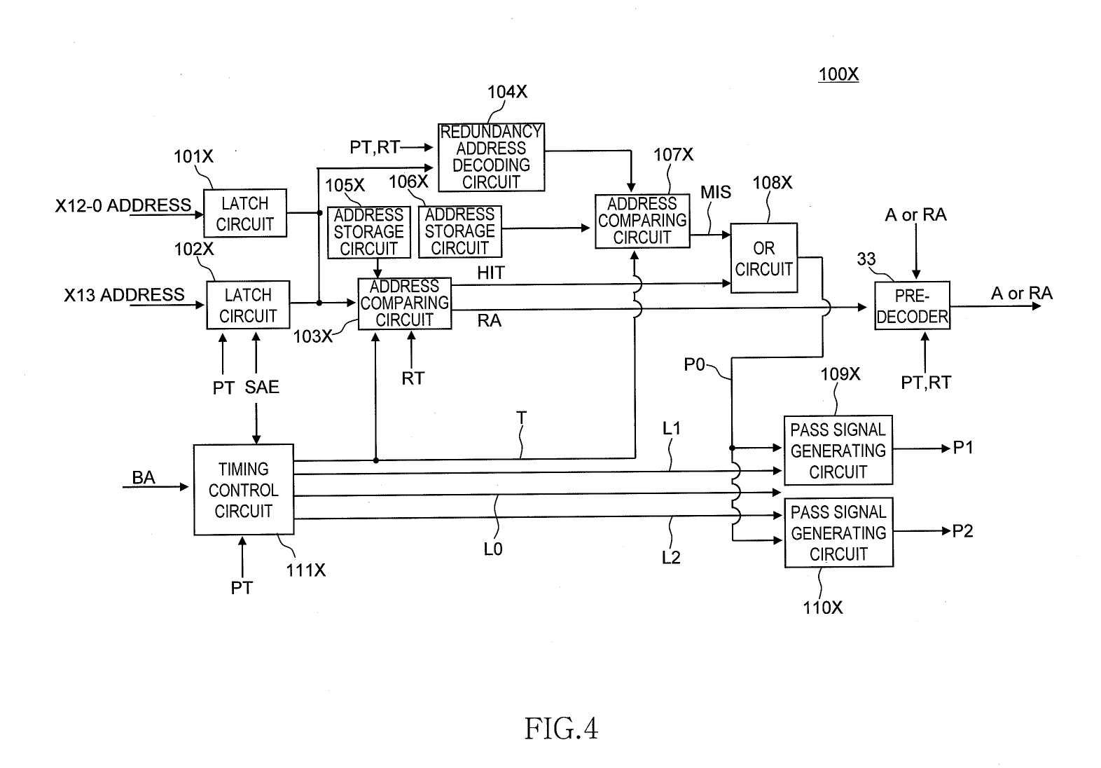

FIG. 4 is a block diagram of a circuit configuration of the X redundancy determining circuit 100X.

As shown in FIG. 4, the X redundancy determining circuit 100X includes a latch circuit 101X that latches the lower row address X12 to X0 and a latch circuit 102X that latches the uppermost row address X13.

The parallel test signal PT and a sense amplifier activation signal SAE are supplied to the latch circuit 102X. The sense amplifier activation signal SAE is a control signal for activating the sense amplifier SA shown in FIG. 2, which is generated by the control circuit 42 shown in FIG. 1. When the parallel test signal PT is not activated, that is, at the time of a normal operation, the latch circuit 102X latches an input row address X13 as it is. On the other hand, when the parallel test signal PT is activated, that is, at the time of a parallel test, the latch circuit 102X latches Low level (=0) and outputs it regardless of a logical level of the input row address X13, and then inverts the logical level in response to activation of the sense amplifier activation signal SAE, latches High level (=1), and outputs it.

Outputs of the latch circuits 101X and 102X (=X13 to X0) are supplied to a first address comparing circuit 103X and a redundancy address decoding circuit 104X. The first address comparing circuit 103X is a circuit that compares an input address, which is the outputs of the latch circuits 101X and 102X, with an address stored in a first address storage circuit 105X. The address stored in the first address storage circuit 105X is a row address of a normal memory cell that is replaced by a redundancy memory cell, that is, a defective address. The defective address is detected by an operation test performed on a wafer state, and is stored in an irreversible and nonvolatile manner by fusing a fuse element with an irradiation of a laser beam or an application of a large current. An address of a redundancy word line that becomes a replacement destination is stored in a second address storage circuit 106X.

After comparison of these addresses, when both addresses match with each other (the case of hit), the first address comparing circuit 103X outputs a match signal HIT, and outputs the corresponding redundancy address RA by referring to the address storage circuit 106X, such that the defective address A is converted into the redundancy address RA. The converted redundancy address RA is supplied to the pre-decoder 33.

As described above, the pre-decoder 33 pre-decodes the redundancy address RA when the comparison result is hit, and pre-decodes the regular address A when the result is miss-hit, which is an operation in the normal operation mode. However, when the parallel test signal PT is activated, the pre-decoder 33 outputs a pre-decode address in which the logical value of the uppermost bit X13 of the input regular address A is invalidated, regardless of the result (that is, even when the result is hit). Furthermore, when both the parallel test signal PT and the redundancy test signal RT are activated, the pre-decoder 33 outputs a pre-decode address in which the logical value of the uppermost bit X13 of the redundancy address RA is invalidated.

The redundancy test signal RT is supplied to the first address comparing circuit 103X, and when the redundancy test signal RT is activated, the first address comparing circuit 103X stops its operation.

Meanwhile, the parallel test signal PT and the redundancy test signal RT are supplied to the redundancy address decoding circuit 104X, and when both the parallel test signal PT and the redundancy test signal RT are activated, the redundancy address decoding circuit 104X decodes the input address, and outputs a decoded address to a second address comparing circuit 107X. The second address comparing circuit 107X is a circuit that compares an output of the redundancy address decoding circuit 104X with an address stored in the address storage circuit 106X (a replacement destination address), and detects match or mismatch of these addresses. When both addresses match with each other, it means that the address is used as the replacement destination. On the other hand, when both addresses mismatch with each other, it means that the address is not used as the replacement destination. When both addresses mismatch with each other, the second address comparing circuit 107X outputs a mismatch signal MIS. The mismatch signal MIS is input to an OR circuit 108X together with the match signal HIT.

The OR circuit 108X is a circuit that activates a pass signal P0 as its output, in response to activation of either one of the match signal HIT and the mismatch signal MIS. Therefore, the pass signal P0 is activated when a word line of a replaced address (a defective address) is to be accessed in a test of the normal cell area 200 in the parallel test mode (the first parallel test mode) or when a redundancy word line of an address not used as the replacement destination is to be accessed in a test of the redundancy cell area 201 in the parallel test mode (the second parallel test mode). The pass signal P0 is commonly supplied to pass signal generating circuits 109X and 110X.

The pass signal generating circuits 109X and 110X are circuits that latch the pass signal P0 in synchronization with latch signals L1 and L2 supplied from a timing control circuit 111X, respectively, and outputs of the pass signal generating circuits 109X and 110X are used as pass signals P1 and P2, respectively. Therefore, the pass signals P1 and P2 show a logical level (active/deactive) of the pass signal P0 at the time when the latch signals L1 and L2 are activated, respectively. The latch contents of the pass signal generating circuits 109X and 110X are reset by a stop signal L0 supplied from the timing control circuit 111X.

The timing control circuit 111X receives a bank active signal BA, the parallel test signal PT, and the sense amplifier activation signal SAE supplied from the control circuit 42 shown in FIG. 1, and based on those signals, generates a comparison timing signal T, the latch signals L1 and L2, and the stop signal L0. Specifically, when the parallel test signal PT is not activated, that is, in the normal operation mode, the timing control circuit 111X outputs the comparison timing signal T based on the bank active signal BA. Because the comparison timing signal T is supplied to the first address comparing circuit 103X, the first address comparing circuit 103X can compare the addresses at a right timing.

On the other hand, when the parallel test signal PT is activated, that is, in the parallel test mode, the timing control circuit 111X outputs the comparison timing signal T based on the bank active signal BA and the sense amplifier activation signal SAE, and at the same time, outputs the latch signal L1 based on the bank active signal BA, and outputs the latch signal L2 based on the sense amplifier activation signal SAE. The timing control circuit 111X then outputs the stop signal L0 in response to deactivation of the bank active signal BA.

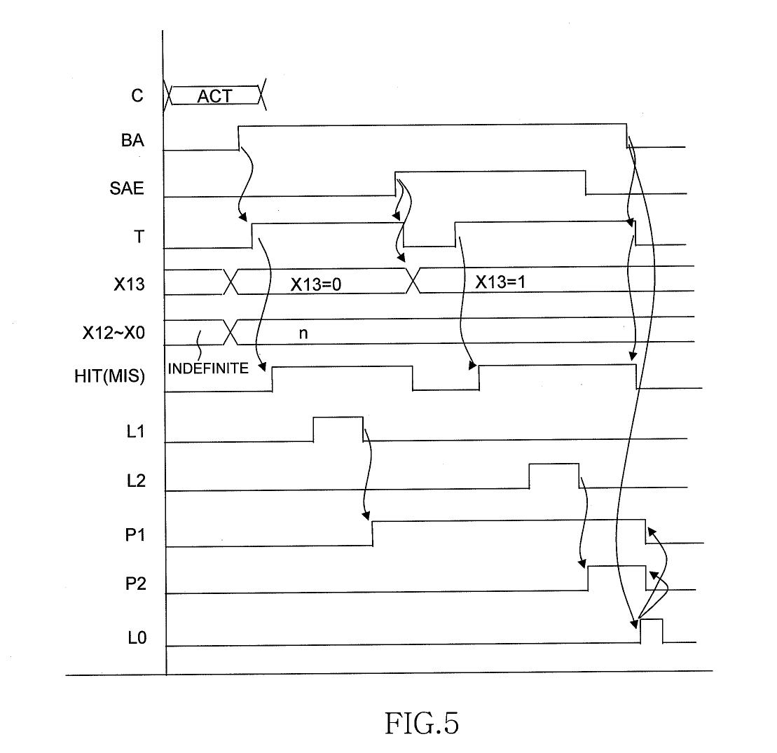

FIG. 5 is a timing chart showing an operation of the X redundancy determining circuit 100X in the first parallel test mode.

As shown in FIG. 5, in the parallel test mode, when an active command ACT and a row address are input from the outside, the bank active signal BA is activated in response to the input. When the bank active signal BA is activated, the timing control circuit 111X outputs the comparison timing signal T. By this operation, the first address comparing circuit 103X performs a comparison of the input address with an address stored in the first address storage circuit 105X. At this time, because the uppermost bit X13 output from the latch circuit 102X is Low level (=0), the uppermost bit X13 of the input address is forcibly set to Low level (=0).

When the comparison result indicates that both addresses match with each other, the match signal HIT is activated, and the match signal HIT is latched in the pass signal generating circuit 109X in synchronization with the latch signal L1. Therefore, when an address replacement is performed in the first memory block MB1, the pass signal P1 is activated.

Thereafter, when the sense amplifier activation signal SAE is activated, the uppermost bit X13 output from the latch circuit 102X is inverted to High level (=1). By this operation, the uppermost bit X13 of the input address is caused to be forcibly set to High level (=1). In synchronization with the comparison timing signal T output again, a comparison of the addresses is performed by the first address comparing circuit 103X.

When the comparison result indicates that both addresses match with each other, the match signal HIT is activated, and the match signal HIT is latched in the pass signal generating circuit 110X in synchronization with the latch signal L2. Therefore, when an address replacement is performed in the second memory block MB2, the pass signal P2 is activated.

As the bank active signal BA is turned to deactivation level, the timing control circuit 111X outputs the stop signal L0, and the pass signals P1 and P2 are then returned to the deactivation level.

In this manner, in the present embodiment, the normal cell areas 200 of the memory blocks MB1 and MB2 are simultaneously accessed in the first parallel test mode, two types of address obtained by inverting the uppermost bit X13 are sequentially compared by the first address comparing circuit 103X, and the pass signals P1 and P2 are generated based on the comparison result. Therefore, the test can be properly performed for a word line that is not replaced, and the test can be passed for a word line that is replaced.

Although the parallel test for the normal cell area 200 has been explained above, the same operation is performed in a test for the redundancy cell area 201, that is, the second parallel test mode, such that the test can be properly performed for a redundancy word line that is used as a replacement destination, and the test can be passed for a redundancy word line that is not used as the replacement destination.

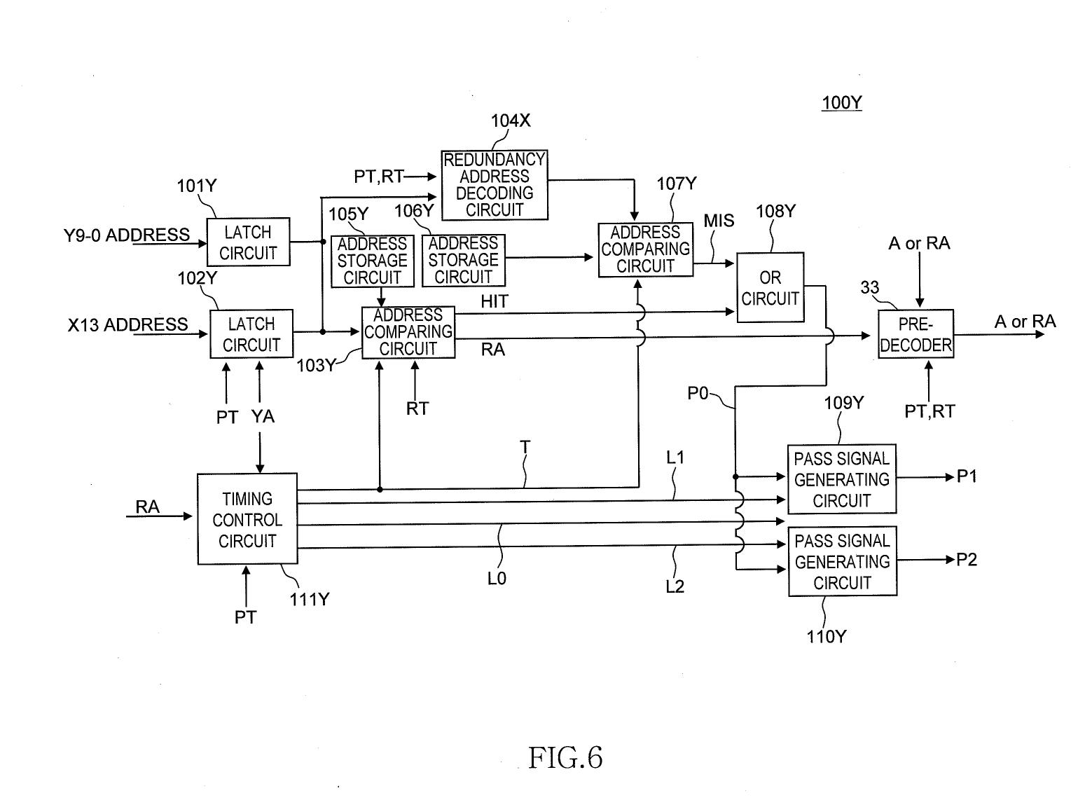

FIG. 6 is a block diagram of a circuit configuration of the Y redundancy determining circuit 100Y.

As shown in FIG. 6, the Y redundancy determining circuit 100Y has the same circuit configuration as the X redundancy determining circuit 100X shown in FIG. 4, except that a column address is used instead of a row address. That is, column addresses Y9 to Y0 are supplied to a latch circuit 101Y instead of the lower addresses X12 to X0 of the row address. A column address of a normal memory cell that is replaced by a redundancy memory cell and an address of a redundancy bit line that becomes a replacement destination are stored in address storage circuits 105Y and 106Y, respectively. In a latch circuit 102Y, the uppermost bit X13 of the row address is supplied in the same manner as the X redundancy determining circuit 100X. In a timing control circuit 111Y, a read active signal RA is supplied instead of the bank active signal BA. Furthermore, in the latch circuit 102Y and the timing control circuit 111Y, a column activation signal YA is supplied instead of the sense amplifier activation signal SAE.

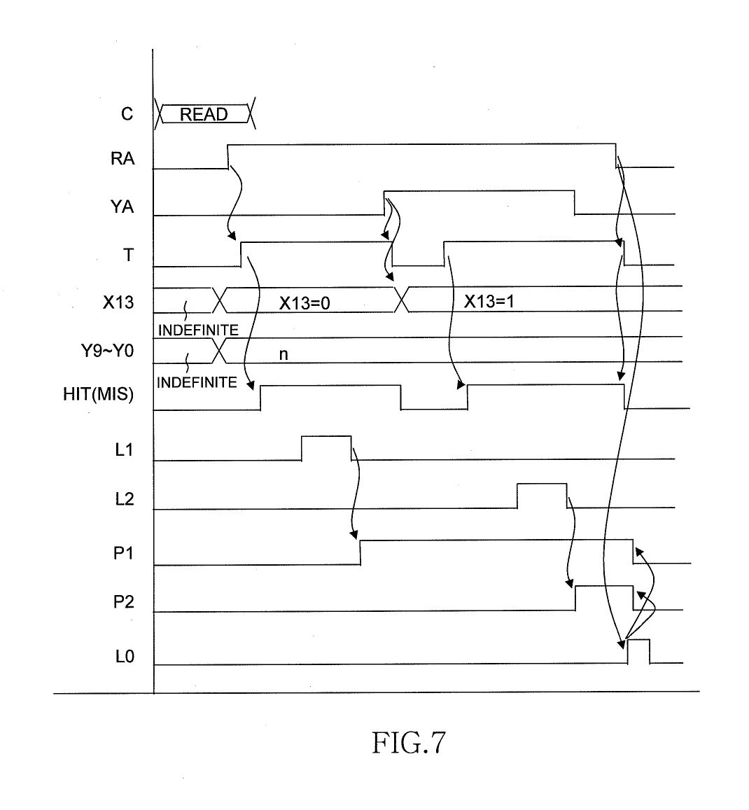

FIG. 7 is a timing chart showing an operation of the Y redundancy determining circuit 100Y in the first parallel test mode.

As shown in FIG. 7, the operation of the Y redundancy determining circuit 100Y in the parallel test mode is the same as that of the X redundancy determining circuit 100X shown in FIG. 5, except that a read command READ and a column address are input from the outside and a read active signal RA is activated in response to the input. By this operation, in a test of the normal cell area 200, the test can be properly performed for a bit line that is not replaced, and the test can be passed for a bit line that is replaced. In a test of the redundancy cell area 202, the test can be properly performed for a redundancy bit line that is used as a replacement destination, and the test can be passed for a redundancy bit line that is not used as the replacement destination.

It is apparent that the present invention is not limited to the above embodiments, but may be modified and changed without departing from the scope and spirit of the invention.

What is claimed is:

1. A semiconductor memory device comprising:
a first memory block and a second memory block each including a normal cell area having a plurality of normal memory cells and a redundancy cell area having a plurality of redundancy memory cells for replacing a defective memory cell among the normal memory cells;
a redundancy determining circuit that can enter at least a normal operation mode in which either one of the first and second memory blocks is accessed and a parallel test mode in which both the first and second memory blocks are simultaneously accessed; and
a verifying circuit that verifies data read from the first and second memory blocks in the parallel test mode, wherein
the redundancy determining circuit supplies the verifying circuit with a pass signal in response to a fact that a replacement from the normal memory cell to be accessed with the redundancy memory cell is performed in at least one of the first and second memory blocks when accessing the normal cell areas of the first and second memory blocks simultaneously in the parallel test mode, and
the verifying circuit passes verification of data read from the normal cell area of the memory block in which the replacement is performed and exclusively performs verification of data read from the normal cell area of the memory block in which replacement is not performed based on the pass signal.

2. The semiconductor memory device as claimed in claim 1, wherein
the redundancy determining circuit supplies the verifying circuit with the pass signal in response to a fact that the redundancy memory cell to be accessed is not used as a replacement destination for the defective memory cell among the normal memory cells in at least one of the first and second memory blocks when accessing the redundant cell areas of the first and second memory blocks simultaneously in the parallel test mode, and
the verifying circuit passes verification of data read from the redundancy cell area of the memory block in which the replacement is not performed, and exclusively performs verification of data read from the redundancy cell area of the memory block in which replacement is performed based on the pass signal.

3. The semiconductor memory device as claimed in claim 1, wherein the redundancy determining circuit supplies a same lower address to the first and second memory blocks simultaneously in the parallel test mode.

4. The semiconductor memory device as claimed in claim 3, wherein the redundancy determining circuit includes:
a first address storage circuit that stores therein an defective address of the defective memory cell among the normal memory cells to be replaced;
an address latch circuit that latches an upper address for distinguishing the first memory block from the second memory block in the parallel test mode; and
a first address comparing circuit that compares an address formed by the upper address and the lower address with the defective address stored in the first address storage circuit, and wherein
the address latch circuit sequentially changes the upper address in the parallel test mode, so that the first address comparing circuit sequentially compares the defective address with addresses assigned to the first and second memory blocks.

5. The semiconductor memory device as claimed in claim 4, wherein the redundancy determining circuit further includes:
a second address storage circuit that stores therein a destination address of the redundancy memory cell that is used for the replacement destination; and
a second address comparing circuit that compares an address formed by the upper address and the lower address with the destination address stored in the second address storage circuit, and wherein
the second address comparing circuit sequentially compares the destination address with addresses assigned to the first and second memory blocks.

6. A testing method of a semiconductor memory device that includes a first memory block and a second memory block each having a normal cell area having a plurality of normal memory cells and a redundancy cell area having a plurality of redundancy memory cells for replacing a defective memory cell among the normal memory cells, the method comprising:
accessing the normal cell areas of the first and second memory blocks simultaneously; and
verifying data read from the first and second memory blocks, wherein
if the normal memory cell to be accessed is replaced with the redundant memory cell in at least one of the first and second memory blocks, verifying is passed with respect to a memory block in which a replacement is performed, and exclusively verifying the read data with respect to a memory block in which a replacement is not performed.

7. The testing method of a semiconductor memory device as claimed in claim 6, further comprising accessing the redundancy cell areas of the first and second memory blocks simultaneously in the parallel test mode, wherein
if the redundant memory cell to be accessed is not used as a replacement destination for the defective memory cell among the normal memory cells in at least one of the first and second memory blocks, verifying is passed with respect to a memory block in which a replacement is not performed, and exclusively verifying the read data with respect to a memory block in which a replacement is performed.
